(19) United States
(12) Patent Application Publication
(10) Pub. No.: US 2026/0068407 A1
(43) Pub. Date: Mar. 5, 2026

(54) DISPLAY APPARATUS

(71) Applicant: SAMSUNG ELECTRONICS CO., LTD., Suwon-si (KR)

(72) Inventors: Taebae KIM, Suwon-si (KR); Sanghyun SOHN, Suwon-si (KR); Dongkyu CHOI, Suwon-si (KR)

(73) Assignee: SAMSUNG ELECTRONICS CO., LTD., Suwon-si (KR)

(21) Appl. No.: 19/267,110

(22) Filed: Jul. 11, 2025

Related U.S. Application Data
(63) Continuation of application No. PCT/KR2025/009231, filed on Jun. 30, 2025.

(30) Foreign Application Priority Data
Sep. 4, 2024 (KR) 10-2024-0120386
Dec. 4, 2024 (KR) 10-2024-0178940

(51) Int. Cl. H10H 29/855; H10H 29/14; H10H 29/85

(52) U.S. Cl. CPC H10H 29/8552; H10H 29/142; H10H 29/8506

(57) ABSTRACT

A display apparatus includes: a first light source configured to emit light visible from a first viewpoint; a second light source arranged in a row with the first light source in a first direction and configured to emit light visible from a second viewpoint; and a multi-view lens configured to refract the light emitted from the first light source toward the first viewpoint and to refract the light emitted from the second light source toward the second viewpoint, wherein each of the first light source and the second light source includes: a light emitter; and a slit cover covering a portion of the light emitter between the light emitter and the at least one multi-view lens, wherein the slit cover includes a light source slit having a first width and is configured to allow the light emitted from the light emitter to pass through the light source slit.

### CROSS-REFERENCE TO RELATED APPLICATIONS

This application is a by-pass continuation of International Application No. PCT/KR2025/009231, filed on Jun. 20, 2025, which is based on and claims priority to Korean Patent Application No. 10-2024-0120386, filed in the Korean Intellectual Property Office on Sep. 4, 2024, and Korean Patent Application No. 10-2024-0178940, filed in the Korean Intellectual Property Office on Dec. 4, 2024, the disclosures of which are incorporated by reference herein in their entireties.

### BACKGROUND

### 1. Field

The disclosure relates to a display apparatus.

### 2. Description of Related Art

The display apparatus is a kind of output device for displaying obtained or stored electrical information for the user by converting the electrical information to visual information, and is used in various fields such as homes or work places.

There are many different display apparatuses such as monitor devices connected to personal computers (PCs) or server computers, portable computer systems, global positioning system (GPS) terminals, general television sets, Internet protocol televisions (IPTVs), portable terminals, e.g., smart phones, tablet PCs, personal digital assistants (PDAs), and cellular phones, various display apparatuses for reproducing images like advertisements or films, or other various kinds of audio/video systems.

The display apparatus may include a type that provides the same image to different viewpoints to look at the screen, and a multi-view display type that provides different images depending on the viewpoint.

The multi-view display apparatus may provide a different image at each viewpoint by modulating external light or light irradiated from a built-in light source. To provide a different image at each viewpoint, there are a holographic method and a stereoscopic method.

The holographic method is to provide a different image at each viewpoint by using coherent light interference.

The stereoscopic method is to divide multiple different two-dimensional (2D) images by viewpoint and provide them.

The stereoscopic method includes an auto-stereoscopic method that forms a field of view by separating an image from the display apparatus. The auto-stereoscopic type is classified into a parallax barrier type using a parallax barrier, a lenticular lens type, etc.

The lenticular lens type is to provide different images at different viewpoints by refracting light entering a lenticular lens from a pixel to be emitted in a desired direction.

### SUMMARY

Provided is a display apparatus having a structure configured to provide different images at different viewpoints.

Further, provided is a display apparatus having a structure configured to narrow a radiation angle of light emitted from a light source.

Further, provided is a display apparatus having a structure configured to narrow the width of light entering a multi-view lens.

Further, provided is a display apparatus having a structure configured to increase the number of different viewpoints formed in a viewing area.

Further, provided is a display apparatus having a structure configured to reduce noise of an image and improve image quality.

Technological objectives of the disclosure are not limited to what are mentioned above, and throughout the specification, it will be clearly appreciated by those of ordinary skill in the art that there may be other technological objectives unmentioned.

According to an aspect of the disclosure, a display apparatus may include: a first light source configured to emit light visible from a first viewpoint; a second light source arranged in a row with the first light source in a first direction and configured to emit light visible from a second viewpoint different from the first viewpoint; and at least one multi-view lens configured to refract the light emitted from the first light source to proceed toward the first viewpoint and to refract the light emitted from the second light source to proceed toward the second viewpoint. Each of the first light source and the second light source may include: a light emitter; and a slit cover covering a portion of the light emitter between the light emitter and the at least one multi-view lens, wherein the slit cover includes a light source slit having a first width and is configured to allow the light emitted from the light emitter to pass through the light source slit.

The light source slit of the slit cover of each of the first light source and the second light source may extend in a direction that is perpendicular to the first direction.

The light source slit of the slit cover of each of the first light source and the second light source may extend in a direction that is perpendicular to a direction in which the first viewpoint and the second viewpoint are arranged.

The at least one multi-view lens may include a plurality of multi-view lenses. The light source slit of the slit cover of each of the first light source and the second light source may extend in a direction that is perpendicular to a direction in which the plurality of multi-view lenses are arranged.

The light emitter of each of the first light source and the second light source may include: a first light emitter configured to emit light of first color; a second light emitter configured to emit light of second color different from the first color; and a third light emitter configured to emit light of third color different from the first color and the second color. A direction in which the first light emitter, the second light emitter and the third light emitter are arranged may be parallel with a direction in which the light source slit of the slit cover of each of the first light source and the second light source extends.

The display apparatus may further include: an entrance surface cover between the at least one multi-view lens and the first light source and the second light source, wherein the entrance surface cover includes a lens slit having a second width. The lens slit may be configured to allow light having passed through the light source slit of one of the first light source or the second light source to pass through the entrance surface cover and enter the at least one multi-view lens.

The second width may be equal to or smaller than the first width.

The entrance surface cover may be on an entrance surface of the at least one multi-view lens. The entrance surface of the at least one multi-view lens may be adjacent to the first light source and the second light source.

The entrance surface cover may include a light absorber coated on the entrance surface of the at least one multi-view lens.

The lens slit may include: a first lens slit configured to allow at least a portion of light having passed through the light source slit of the first light source to pass through the entrance surface cover; and a second lens slit arranged in parallel with the first lens slit and configured to allow at least a portion of light having passed through the light source slit of the second light source to pass through the entrance surface cover. A center of the light emitter of the first light source, a center of the light source slit of the first light source and a center of the first lens slit may be arranged in a line. A center of the light emitter of the second light source, a center of the light source slit of the second light source and a center of the second lens slit may be arranged in a line.

Each of the first light source and the second light source may further include a light source case accommodating the light emitter. The slit cover of each of the first light source and the second light source may be on a side of the light source case facing toward the at least one multi-view lens.

Each of the first light source and the second light source may further include a transparent resin in the light source case enclosing the light emitter. The slit cover of each of the first light source and the second light source may cover a portion of the transparent resin on a side of the transparent resin facing toward the at least one multi-view lens.

The slit cover of each of the first light source and the second light source may include a light blocker around the light source slit and configured to block a portion of light emitted from the light emitter.

The light blocker of each of the first light source and the second light source may include a black coating layer configured to absorb a portion of light emitted from the light emitter.

The light blocker of each of the first light source and the second light source may include a reflective layer configured to reflect a portion of light emitted from the light emitter toward the light emitter.

According to an aspect of the disclosure, a display apparatus may include: a first light source configured to emit light visible from a first viewpoint; a second light source arranged in a row with the first light source in a first direction and configured to emit light visible from a second viewpoint different from the first viewpoint; and a multi-view lens including an entrance surface on a side of the multi-view lens facing the first light source and the second light source, the entrance surface including a first lens slit corresponding to the first light source and a second lens slit corresponding to the second light source. The multi-view lens may be configured to refract the light emitted from the first light source to proceed toward the first viewpoint and to refract the light emitted from the second light source to proceed toward the second viewpoint. Each of the first light source and the second light source may include: a light emitter; and a light source case accommodating the light emitter. The light source case may include: a slit cover on a side of the light source case adjacent to the entrance surface of the multi-view lens, the slit cover covering a portion of the light emitter between the light emitter and the multi-view lens. The slit cover may include a light source slit having a first width; and a plurality of walls surrounding the light emitter. An inner surface of at least one of the plurality of walls may include a slanted surface and an interior width of the light source case may increase in a direction moving away from the light emitter and toward the slit cover.

The light source slit of the slit cover of each of the first light source and the second light source may extend in a direction that is perpendicular to the first direction.

The light source slit of the slit cover of each of the first light source and the second light source may extend in a direction that is perpendicular to a direction in which the first viewpoint and the second viewpoint are arranged.

The multi-view lens may include a plurality of multi-view lenses. The light source slit of the slit cover of each of the first light source and the second light source may extend in a direction that is perpendicular to a direction in which the plurality of multi-view lenses are arranged.

The first lens slit and the second lens slit may have a second width, and the second width may be equal to or smaller than the first width.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a perspective view of a display apparatus, according to an embodiment of the disclosure;

FIG. 2 illustrates images provided at multiple viewpoints from a display apparatus, according to an embodiment of the disclosure;

FIG. 3 is an exploded perspective view of a display apparatus, according to an embodiment of the disclosure;

FIG. 4 illustrates a light source array of a display apparatus and light sources included therein, according to an embodiment of the disclosure;

FIG. 5 is a perspective view illustrating a light source array and a multi-view lens of a display apparatus, according to an embodiment of the disclosure;

FIG. 6 is an enlarged cross-sectional view of a light source array, an entrance surface cover and a multi-view lens of a display apparatus, according to an embodiment of the disclosure;

FIG. 7 is a perspective view illustrating a light source of a display apparatus, according to an embodiment of the disclosure;

FIG. 8 is a front view illustrating a light source of a display apparatus, according to an embodiment of the disclosure;

FIG. 9 is an enlarged cross-sectional view illustrating a light source and a light source substrate of a display apparatus, according to an embodiment of the disclosure;

FIG. 10 is an enlarged cross-sectional view of a light source array, an entrance surface cover and a multi-view lens of a display apparatus, according to an embodiment of the disclosure;

FIG. 11 is an enlarged cross-sectional view of a light source array, an entrance surface cover and a multi-view lens of a display apparatus, according to a comparative embodiment;

FIG. 12 is an enlarged cross-sectional view of a light source array, an entrance surface cover and a multi-view lens of a display apparatus, according to an embodiment of the disclosure; and

FIG. 13 is an enlarged cross-sectional view of a light source array and a multi-view lens of a display apparatus, according to an embodiment of the disclosure.

### DETAILED DESCRIPTION

Embodiments and features as described and illustrated in the disclosure are merely examples, and there may be various modifications replacing the embodiments and drawings at the time of filing this application.

Throughout the drawings, like reference numerals refer to like parts or components.

The terminology used herein is for the purpose of describing particular embodiments only and is not intended to limit the disclosure. It is to be understood that the singular forms “a,” “an,” and “the” include plural references unless the context clearly dictates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The terms including ordinal numbers like “first” and “second” may be used to explain various components, but the components are not limited by the terms. The terms are only for the purpose of distinguishing a component from another. For example, a first element could be termed a second element and vice versa, without departing from the scope of the disclosure. Descriptions shall be understood as to include any and all combinations of one or more of the associated listed items when the items are described by using the conjunctive term “˜ and/or ˜,” or the like.

The terms “unit”, “module”, “member”, or “block” may refer to what is implemented in software or hardware, and a plurality of units, modules, members, or blocks may be integrated in one component or the unit, module, member, or block may include a plurality of components, depending on the embodiment of the disclosure.

It will be understood that when an element is referred to as being “connected” with or to another element, it can be directly or indirectly connected to the other element, wherein the indirect connection may include “connection via a wireless communication network”.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

One or more embodiments of the disclosure will now be described in detail with reference to the accompanying drawings.

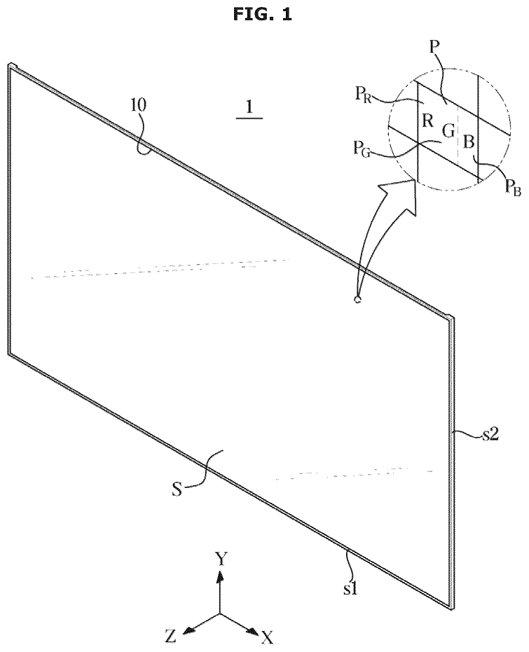

In describing the one or more embodiments of the disclosure with reference to FIGS. 1 to 13, the terms “front-back direction or forward or rearward direction”, “vertical direction”, “horizontal (left-right) direction”, etc., as herein used are defined with respect to the drawings, and the shape and position of each component are not limited by the terms. For example, the term “front-back direction or forward or rearward direction” may refer to a direction parallel to the direction Z with respect to the drawings. For example, the “vertical direction” may refer to a direction parallel to the direction Y with respect to the drawings. For example, the term “horizontal (left-right) direction” may refer to a direction parallel to the direction X with respect to the drawings.

FIG. 1 is a perspective view of a display apparatus, according to an embodiment of the disclosure.

Referring to FIG. 1, a display apparatus 1 according to one or more embodiments of the disclosure is a device that is able to process an image signal received from the outside and visually present the processed image.

For example, the display apparatus 1 may be implemented in various types such as a television (TV), a monitor, a kind of computer output device, a portable multimedia device, a portable communication device, etc. For example, the display apparatus 1 may be a large format display (LFD) installed outdoors such as on a rooftop or at a bus stop. The display apparatus 1 is not, however, exclusively installed outdoors, but may be installed at any place, even indoors with a lot of foot traffic, e.g., at subway stations, shopping malls, theaters, offices, stores, etc. In one or more embodiments of the disclosure, the display apparatus 1 may be any device that provides a visual image, without being limited to the aforementioned types of devices.

For example, the display apparatus 1 may be installed in a standing type on the floor or on the furniture indoors or outdoors. For example, the display apparatus 1 may be installed on or inside a wall of a building or other structures. For example, the display apparatus 1 may be installed on a wall through a wall-mounted device.

Although the display apparatus 1 is illustrated as a flat display apparatus with a flat screen in FIG. 1, the display apparatus 1 according to one or more embodiments of the disclosure may also include a curved display apparatus or a bendable or flexible display apparatus that is switchable between a flat state and a curved state. The configuration of the disclosure as will be described below may be applied to many different forms of display apparatuses regardless of the screen size or ratio of the display apparatuses.

The display apparatus 1 may receive contents including video and audio signals from various content sources and output video and audio corresponding to the video and audio signals. For example, the display apparatus 1 may receive content data through a broadcast receiving antenna or a cable, receive content data from a content reproducing device, or receive content data from a content providing server of a content provider.

The display apparatus 1 may display an image corresponding to the video data, and output sound corresponding to the audio data. For example, the display apparatus 1 may reconstruct a plurality of image frames included in the video data and display the plurality of image frames successively. Furthermore, the display apparatus 1 may reconstruct an audio signal included in the audio data and successively output sounds based on the audio signal.

The display apparatus 1 may include a screen S configured to display an image. The screen S may be arranged on one side of the display apparatus 1. The side on which the screen S is arranged may be defined to be the front side of the display apparatus 1. The screen S may be arranged on the front of the display apparatus 1. The screen S may be configured to display an image in the forward direction. For example, the screen S may display still images or moving images. For example, the screen S may display two dimensional (2D) plane images, or three dimensional (3D) stereographic images.

A plurality of pixels P may be formed on the screen S. An image displayed on the screen S may be formed by light emitted by each of the plurality of pixels P. For example, the light emitted by the plurality of pixels P may be combined like mosaics into an image on the screen S.

The plurality of pixels P may each emit light in various colors and brightnesses. Specifically, each of the plurality of pixels P may include subpixels P_{R}, P_{G}, and P_{B}, and the subpixels P_{R}, P_{G}, and P_{B} may include a red subpixel P_{R} to emit red light, a green subpixel P_{G} to emit green light, and blue subpixel P_{B} to emit blue light. For example, the red light may have wavelengths of about 620 nanometers (nm, i.e., a billionth of a meter) to about 750 nm; green light may have wavelengths of about 495 nm to about 570 nm; blue light may have wavelengths of about 450 nm to about 495 nm.

By combinations of the light emitted from each of the red subpixel P_{R}, the green subpixel P_{G}, and the blue subpixel P_{B}, each of the plurality of pixels P may emit various brightnesses and colors of light.

For example, the screen S of the display apparatus 1 may be shaped substantially like a rectangle. The screen S may have a first side s1 and a second side s2. The screen S may have the shape of a rectangle with a pair of first sides s1 parallel to each other and a pair of second sides s2 parallel to each other.

For example, the first side s1 of the screen S may be in parallel with the horizontal direction X, and the second side s2 of the screen S may be in parallel with the vertical direction Y. For example, the first side s1 of the screen S may be the long side and the second side s2 of the screen S may be the short side. As shown in FIG. 1, the screen S may have the long side (e.g., the first side s1) parallel to the horizontal direction X and the short side (e.g., the second side) parallel to the vertical direction Y, but the disclosure is not limited thereto, and the screen S of the display apparatus 1 according to one or more embodiments of the disclosure may have the long side parallel to the vertical direction Y and the short side parallel to the vertical direction X. Alternatively, the screen S of the display apparatus 1 may be shaped like a square with the first side s1 and the second side s2, the lengths of which are almost the same. Alternatively, the screen S of the display apparatus 1 may have other polygonal shapes than the rectangular shape, or a circular shape.

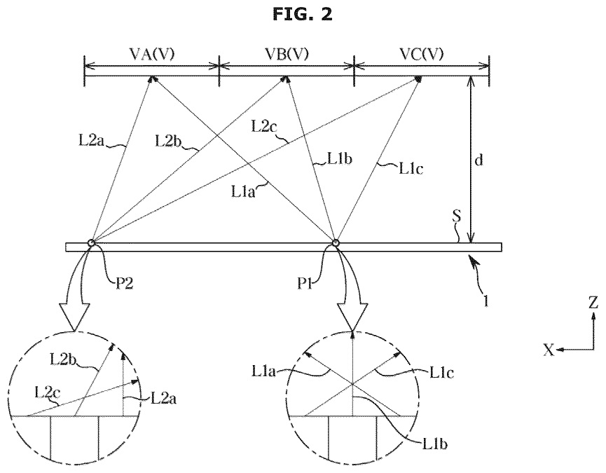

FIG. 2 illustrates images provided to multiple viewpoints from a display apparatus, according to an embodiment of the disclosure.

Referring to FIG. 2, the display apparatus 1 may be configured to provide different images to different viewpoints V looking at the screen S. The display apparatus 1 may be configured to display different images through the screen S depending on the viewpoint. The display apparatus 1 may use auto-stereoscopy to provide different images depending on the viewpoint by separating and displaying a plurality of different images on the screen S.

The display apparatus 1 may be configured to provide a plurality of different images at multiple viewpoints V. The viewpoints V may be formed in an area (hereinafter, referred to as a viewing area) at a location separated by a certain distance d from the screen S in the forward direction Z, and may be defined as a point for the viewer to watch an image displayed on the screen S. The viewing area may be divided into multiple viewpoints V, which may be arranged in one direction along the viewing area.

The forward direction in which the screen S displays images is defined to be a first direction Z, and the direction in which the multiple viewpoints V are arranged is defined to be a second direction X. The first direction Z may be parallel to a direction in which a light source array 20, as will be described later, emits light. The second direction X may be different from the first direction Z. For example, the second direction X may be perpendicular to the first direction Z, but the disclosure is not limited thereto, and an angle between the first direction Z and the second direction X may not be a right angle. For example, the second direction X may be parallel to the first side s1 of the screen S. For example, the second direction X may be parallel to the long side of the screen S. Alternatively, for example, the second direction X may be parallel to the short side of the screen S. For example, the second direction X may be parallel to the horizontal direction of the display apparatus 1 parallel to the ground. Alternatively, for example, the second direction X may be parallel to the vertical direction of the display apparatus 1 perpendicular to the ground.

A direction that is different from the first direction Z and the second direction X is defined as a third direction Y. For example, the third direction Y may be perpendicular to the first direction Z and the second direction X, but the disclosure is not limited thereto, and the third direction Y may not be perpendicular to the first direction Z or the second direction X. Although the third direction Y is shown as being parallel to the short side of the screen S and parallel to the vertical direction of the display apparatus 1 in the drawings, one or more embodiments of the disclosure are not limited thereto.

The properties of light emitted from the display apparatus 1 may be defined by a light field. The light field may be defined with a function that represents a traveling direction and intensity of light at all points in a 3D space. The display apparatus 1 may control the light field of light emitted from the screen S so that only a particular image is visible at a particular viewpoint among the multiple viewpoints V. By making only a particular image visible at a particular viewpoint, different images may be provided at multiple viewpoints, respectively.

For example, referring to FIG. 2, light L1a that proceeds to a first viewpoint VA from a first point P1 on the screen S, light L1b that proceeds to a second viewpoint VB from the first point P1, and light L1c that proceeds to a third viewpoint VC from the first point P1 may provide different images. A combination of subpixels that provide the light L1a toward the first viewpoint VA from the first point P1 on the screen S, a combination of the subpixels that provide the light L1b toward the second viewpoint VB from the first point P1, and a combination of the subpixels that provide the light L1c toward the third viewpoint VC from the first point P1 may be different form each other. In other words, the viewer may recognize different images when looking at the first point P1 on the screen S at the first viewpoint VA, when looking at the first point P1 on the screen S at the second viewpoint VB, and when looking at the first point P1 on the screen S at the third viewpoint VC. An example of the first point P1 shown in FIG. 2 is taken as being roughly adjacent to the center of the screen S in the second direction X, but it is not limited thereto.

Similarly, for example, referring to FIG. 2, light L2a that proceeds to the first viewpoint VA from a second point P2 on the screen S, light L2b that proceeds to the second viewpoint VB from the second point P2, and light L2c that proceeds to the third viewpoint VC from the second point P2 may provide different images. A combination of subpixels that provide the light L2a toward the first viewpoint VA from the second point P2 on the screen S, a combination of the subpixels that provide the light L2b toward the second viewpoint VB from the second point P2, and a combination of the subpixels that provide the light L2c toward the third viewpoint VC from the second point P2 may be different form each other. In other words, the viewer may recognize different images when looking at the second point P2 on the screen S at the first viewpoint VA, when looking at the second point P2 on the screen S at the second viewpoint VB, and when looking at the second point P2 on the screen S at the third viewpoint VC. An example of the second point P2 shown in FIG. 2 is taken as being roughly adjacent to an edge of the screen S in the second direction X, but it is not limited thereto.

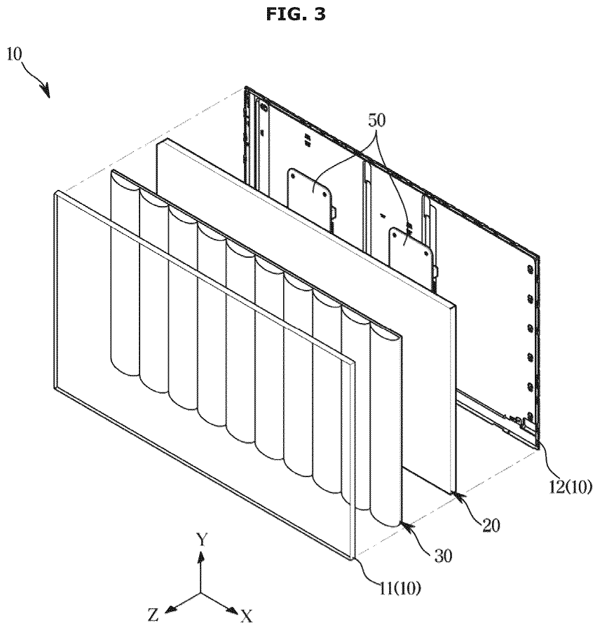

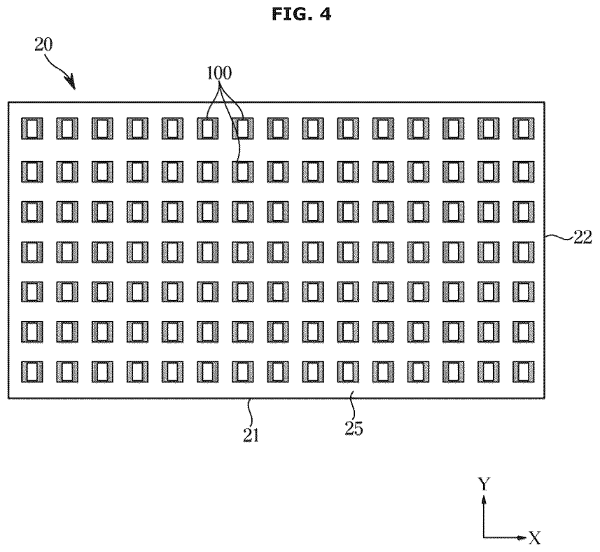

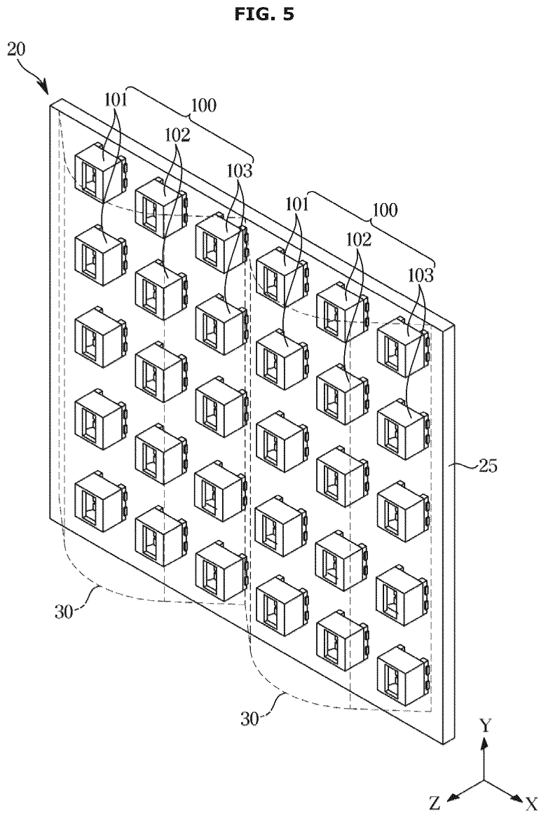

This may enable the viewer to recognize different images displayed on the screen S depending on the viewpoints V. As such, to provide a plurality of different images at a plurality of viewpoints V, the display apparatus 1 may include a multi-view lens 30 (see FIGS. 3 and 5) configured to separate and provide light emitted from a light source 100 (see FIG. 4) at respective viewpoints V. The multi-view lens 30 may also be referred to as a lenticular lens. This will be described in detail later.

Although an example of dividing a viewing area into three viewpoints VA, VB and VC is described above, it is merely for convenience of explanation, and the viewing area may be divided into other various number of viewpoints in one or more embodiments of the disclosure.

In an embodiment of the disclosure, the display apparatus 1 may be configured to provide an image from separate points on the screen S at each of the multiple viewpoints V. For example, the viewpoints VA, VB and VC at which the light L1a, L1b and L1c arrives from the first point P1 may correspond to the viewpoints VA, VB and VC at which the light L2a, L2b and L2c arrives from the second point P2. This may widen the range of the multiple viewpoints V provided by the display apparatus 1, i.e., the display apparatus 1 may provide a wider viewing angle.

Components of the display apparatus 1 for providing different images at multiple viewpoints V will now be described in detail with reference to one or more embodiments of the disclosure.

FIG. 3 is an exploded perspective view of a display apparatus, according to an embodiment of the disclosure. FIG. 4 illustrates a light source array of a display apparatus and light sources included therein, according to an embodiment of the disclosure.

Referring to FIGS. 3 and 4, the display apparatus 1 may include a case 10 to support various components of the display apparatus 1. Various components of the display apparatus 1 may be accommodated in the case 10. The case 10 may define an exterior of the display apparatus 1.

For example, the case 10 may support a light source array 20. For example, the case 10 may support the multi-view lens 30. For example, the case 10 may support a board assembly 50.

The case 10 may include a front chassis 11. For example, the front chassis 11 may support the front surface or side edges of the light source array 20. For example, the front chassis 11 may be shaped almost like a rectangular frame.

The case 10 may include a rear chassis 12. For example, the rear chassis 12 may cover the back of the light source array 20. For example, the rear chassis 12 may support the back of the light source array 20. For example, the rear chassis 12 may support the board assembly 50. For example, the rear chassis 12 may have the form of substantially a flat plate, but the disclosure is not limited thereto.

The display apparatus 1 may include the light source array 20 configured to emit light. The light source array 20 may be configured to emit light in the first direction Z. The light source array 20 may be configured to emit light to provide an image.

For example, the light source array 20 may have the form of substantially a rectangular plate. For example, the light source array 20 may have a shape substantially corresponding to the screen S.

For example, the light source array 20 may have first sides 21 and second sides 22. The light source array 20 may have a pair of first sides 21 parallel to each other and a pair of second sides 22 parallel to each other. For example, the first sides 21 of the light source array 20 may be parallel to the second direction X. For example, the second sides 22 of the light source array 20 may be parallel to the third direction Y. In other words, the first sides 21 of the light source array 20 may be parallel to a direction in which the multiple viewpoints V are divided and arranged (see FIG. 2).

For example, the first sides 21 of the light source array 20 may be parallel to the long sides of the screen S. Alternatively, for example, the first sides 21 of the light source array 20 may be parallel to the short sides of the screen S.

For example, the first sides 21 of the light source array 20 may be parallel to the horizontal direction of the display apparatus 1. Alternatively, for example, the first sides 21 of the light source array 20 may be parallel to the vertical direction of the display apparatus 1.

The light source array 20 may include the plurality of light sources 100. The plurality of light sources 100 may be configured to emit light in substantially the same direction. The plurality of light sources 100 may be configured to emit light in the first direction Z. The light source array 20 may be formed with the plurality of light sources 100 arranged at certain intervals. The intervals between the plurality of light sources 100 may be regular or irregular. For example, the light source array 20 may include the plurality of light sources 100 arranged in rows and columns. The rows of the light sources 100 may extend in the second direction X. The columns of the light sources 100 may extend in the third direction Y.

For example, each of the plurality of light sources 100 may correspond to each pixel P on the screen S. Alternatively, for example, a combination of a certain number of light sources 100 arranged adjacent to each other among the plurality of light sources 100 may correspond to each pixel P on the screen S. Specifically, a certain number (at least one) of the plurality of light sources 100 may form each pixel P on the screen S, and the plurality of light sources 100 may form an image as a whole.

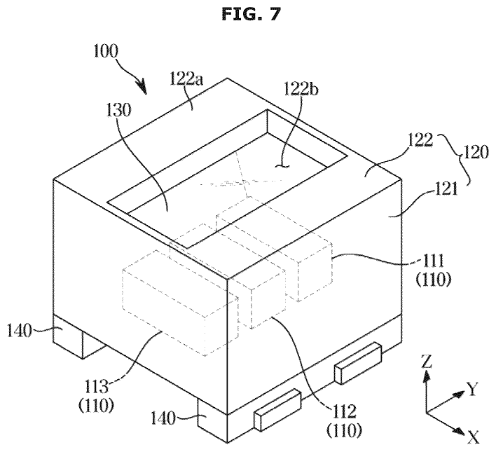

Each of the plurality of light sources 100 may include a light emitter 110 (see FIG. 7). Each of the plurality of light sources 100 may include one or more light emitters 110. The light emitters 110 may be configured to receive a driving voltage and/or driving current to emit light. For example, the light emitters 110 may include light emitting diodes (LEDs).

In an embodiment of the disclosure, the display apparatus 1 may include a self-luminous display apparatus in which the light source array 20 with the plurality of light sources 100, which are LEDs, displays an image by itself. Aside from this, the light source array 20 of the display apparatus 1 may include various types of display panels, e.g., a self-luminous panel such as organic LEDs (OLEDs) and a micro-LED panel, or a non-luminous panel such as a liquid crystal display (LCD) panel. When the light source array 20 is the non-luminous display panel such as the LCD panel, each part of a pixel, e.g., a subpixel, may be defined as the light source 100.

The light source array 20 may include a light source substrate 25 on which the plurality of light sources 100 are mounted. The light source substrate 25 may include a circuit in which the plurality of light sources 100 are electrically connected. The plurality of light sources 100 may receive a driving voltage and/or driving current through the circuit on the light source substrate 25. For example, the light source substrate 25 may have the form of substantially a rectangular plate. The light source substrate 25 on which the whole light sources 100 are mounted may be integrally formed, or may be formed with a plurality of separate light source substrates 25.

The light source array 20 may be configured to emit light to provide different images at different viewpoints. Some of the plurality of light sources 100 may be combined to emit light to provide a particular image (e.g., a first image) to a particular viewpoint (e.g., a first viewpoint) among the multiple viewpoints V, and some others among the plurality of light sources 100 may be combined to emit light to provide another particular image (e.g., a second image that is different from the first image) to another particular viewpoint (e.g., a second viewpoint that is different from the first viewpoint) among the multiple viewpoints V.

The number of the plurality of light sources 100 may be equal to or greater than the number of the plurality of viewpoints V included in the whole viewing angle. The number of columns of the plurality of light sources 100 may be equal to or greater than the number of the plurality of viewpoints V included in the whole viewing angle. The number of the light sources 100 included in one row may be equal to or greater than the number of the plurality of viewpoints V included in the whole viewing angle.

The display apparatus 1 may include the multi-view lens 30 for the light emitted from each of the plurality of light sources 100 to proceed to each set viewpoint V. The multi-view lens 30 may be arranged in the first direction Z (i.e., forward direction) of the light source array 20. The multi-view lens 30 may be arranged in the first direction Z of each of the plurality of light sources 100. The multi-view lens 30 may be configured to make rays emitted from the plurality of light sources 100 proceed to each set viewpoint V. The multi-view lens 30 may be configured to change paths of rays emitted from the plurality of light sources 100 to proceed to each set viewpoint V.

Structure and functions of the multi-view lens 30 will be described later in detail.

The display apparatus 1 may include various board assemblies 50. Electronic parts may be mounted on the board assembly 50, and a circuit including the electronic parts may be arranged on the board assembly 50. For example, the circuit on the board assembly 50 may be formed with a conductive material such as copper Cu printed in a circuit line pattern on an electrically insulating substrate. The board assembly 50 may be configured to control various parts including the light source array 20 to perform the functions of the display apparatus 1 and supply power to the parts.

The board assembly 50 may include various circuit boards such as a main board, a power supply board, a source board, etc.

For example, the main board may control overall operation of the display apparatus 1. The main board may include a processor and a power management device for operating the display apparatus 1. The main board may include a control circuit to control such parts as a communication module, a content receiver for receiving content data from content sources, etc.

For example, the power supply board may be configured to supply power to various parts of the display apparatus 1. The power supply board may include a switched mode power supply (SMPS) board. The power supply board may include a power supply circuit for supplying power to parts such as the light source array 20.

For example, the source board may control the light source array 20. The source board may send a driving signal to the light source array 20 to control operation of each of the plurality of light sources 100. The source board may include a control circuit for controlling the light source array 20.

The circuit boards of the board assembly 50 such as the main board, the power supply board, the source board, etc., may be arranged separately from each other or merged together. When the circuit boards are arranged separately from each other, the circuit boards may be electrically connected to each other to exchange data, signals or power. For example, the circuit boards of the board assembly 50 may be electrically connected to each other via a cable to perform a function to operate the display apparatus 1. The cable may include various types of cables such as a film cable, a flexible flat cable (FFC), flexible printed circuit board (FPCB), etc.

The display apparatus 1 may include the cable that transmits image data from the board assembly 50 to the light source array 20, a display driver integrated circuit (DDI) that processes digital image data to output an analog image signal, etc.

The components of the display apparatus 1 as described above in connection with FIGS. 3 and 4 are merely an example of components to be included in the display apparatus 1 according to an embodiment of the disclosure, but the disclosure is not limited thereto. In one or more embodiments of the disclosure, the display apparatus 1 may include various components to perform various functions of the display apparatus 1.

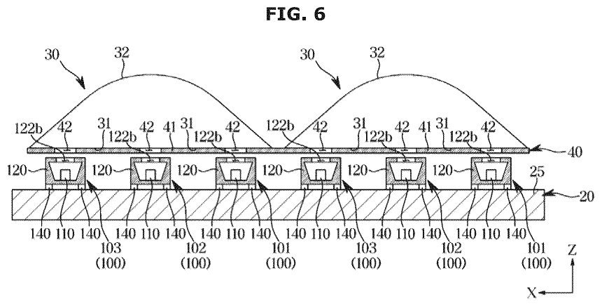

FIG. 5 is a perspective view illustrating a light source array and multi-view lenses of a display apparatus, according to an embodiment of the disclosure. FIG. 6 is an enlarged view of a light source array, an entrance surface cover and a multi-view lens, according to an embodiment of the disclosure.

Referring to FIGS. 5 and 6, the display apparatus 1 according to an embodiment of the disclosure may include the light source array 20 including the plurality of light sources 100, and the multi-view lenses 30 configured to emit light to a set viewpoint among the plurality of viewpoints V by changing the traveling direction of the light emitted from the light source array 20.

The multi-view lenses 30 may be arranged in the first direction Z of the light source array 20. For example, the multi-view lenses 30 may be arranged adjacent to the front surface of the light source array 20. For example, the multi-view lenses 30 may be attached to the front surface of the light source array 20. For example, an entrance surface cover 40 may be arranged between the light source array 20 and the multi-view lens 30, and the multi-view lens 30 may be attached to or arranged adjacent to the front surface of the entrance surface cover 40. For example, an entrance surface 31 of the multi-view lens 30, on which the light from the light source array 20 is incident, may be attached to or arranged adjacent to the front surface of the entrance surface cover 40. In an embodiment in which no entrance surface cover 40 is arranged between the multi-view lens 30 and the light source array 20, the entrance surface 31 of the multi-view lens 30 may be attached to or arranged adjacent to the front surface of the light source array 20.

For example, the multi-view lens 30 may be fixed to the light source array 20 by an adhesive or screws. Apart from this, the multi-view lens 30 and the light source array 20 may be fixed to each other in various ways.

The multi-view lens 30 may be provided in the plural. The plurality of multi-view lenses 30 may be arranged in the first direction Z of the light source array 20. The plurality of multi-view lenses 30 may be arranged in the second direction X. Each of the plurality of multi-view lenses 30 may be configured to emit light that has entered from the plurality of light sources 100 to a set viewpoint V among the plurality of viewpoints V.

Each of the plurality of multi-view lenses 30 may extend in the third direction Y, which is different from the first direction Z and the second direction X. For example, the third direction Y may be perpendicular to the first direction Z and the second direction X. When the plurality of multi-view lenses 30 are arranged in the horizontal direction of the display apparatus 1, each of the plurality of multi-view lenses 30 may extend in the vertical direction. When the plurality of multi-view lenses 30 are arranged in the vertical direction of the display apparatus 1, each of the plurality of multi-view lenses 30 may extend in the horizontal direction. When the plurality of multi-view lenses 30 are arranged in a direction of the long side of the display apparatus 1, each of the plurality of multi-view lenses 30 may extend in a direction of the short side of the display apparatus 1. When the plurality of multi-view lenses 30 extend in the direction of the short side of the display apparatus 1, each of the plurality of multi-view lenses 30 may extend in the direction of the long side of the display apparatus 1.

Alternatively, each of the plurality of multi-view lenses 30 may extend in a direction different from the first direction Z and the second direction X, and the direction may not be perpendicular to the first direction Z and the second direction X. For example, each of the plurality of multi-view lenses 30 may extend in a direction inclined to a direction perpendicular to the first direction Z and the second direction X. When the plurality of multi-view lenses 30 are arranged in the horizontal direction of the display apparatus 1, each of the plurality of multi-view lenses 30 may extend in a direction inclined to the vertical direction. When the plurality of multi-view lenses 30 are arranged in the vertical direction of the display apparatus 1, each of the plurality of multi-view lenses 30 may extend in a direction inclined to the horizontal direction. When the plurality of multi-view lenses 30 are arranged in the direction of the long side of the display apparatus 1, each of the plurality of multi-view lenses 30 may extend in a direction inclined to the direction of the short side of the display apparatus 1. When the plurality of multi-view lenses 30 are arranged in the direction of the short side of the display apparatus 1, each of the plurality of multi-view lenses 30 may extend in a direction inclined to the direction of the long side of the display apparatus 1.

For example, the plurality of multi-view lenses 30 may extend side by side.

The light source array 20 may include the plurality of light sources 100 arranged in parallel with each other. For example, the plurality of light sources 100 may be arranged in the second direction X. The light source array 20 may include columns of light sources 100 arranged in the second direction X and each column of the light sources 100 may extend in the third direction Y. The plurality of light sources 100 may be configured to emit light to be provided to different viewpoints.

Light emitted from a certain number (e.g., at least two) of light sources 100 arranged in the second direction X among the plurality of light sources 100 included in the light source array 20 may enter each of the plurality of multi-view lenses 30. In other words, light emitted from at least two light sources 100 arranged in the second direction X may enter one multi-view lens 30. The light emitted from the at least two light sources 100 arranged in the second direction X may be refracted by the one multi-view lens 30. The one multi-view lens 30 may correspond to at least two light sources 100 arranged in the second direction X. For example, the number of the light sources 100 arranged in the second direction X and corresponding to the one multi-view lens 30 may be at least equal to or greater than the number of viewpoints V.

An embodiment in which the light source array 20 includes a first light source 101, a second light source 102 and a third light source 103 arranged side by side (i.e., in a row) and corresponding to one multi-view lens 30 and the plurality of viewpoints V include the first viewpoint VA, the second viewpoint VB and the third viewpoint VB arranged in parallel with each other will now be described with reference to an embodiment illustrated in FIGS. 5 and 6. The disclosure is not, however, limited thereto, and in one or more embodiments, the light source array 20 may include various numbers of light sources 100 arranged in the second direction X and corresponding to one multi-view lens 30. In one or more embodiments, the light source array 20 may include the first light source 101 and the second light source 102 arranged in the second direction X and corresponding to the one multi-view lens 30, and the plurality of viewpoints V may include the first viewpoint VA and the second viewpoint VB. In one or more embodiments, the light source array 20 may include four or more light sources arranged in the second direction X and corresponding to one multi-view lens 30, and the plurality of viewpoints V may include four or more viewpoints.

The first light source 101 as will be described below may correspond to one of the plurality of multi-view lenses 30, belong to one of the rows of the light sources 100 included in the light source array 20 and emit light to be provided to the first viewpoint VA among the plurality of viewpoints V, and the first light source 101 may be provided in the plural, each of which is included in each of the plurality of rows, corresponding to each of the plurality of multi-view lenses 30. The second light source 102 as will be described below may correspond to one of the plurality of multi-view lenses 30, belong to one of the rows of the light sources 100 included in the light source array 20 and emit light to be provided to the second viewpoint VB among the plurality of viewpoints V, and the second light source 102 may be provided in the plural, each of which is included in each of the plurality of rows, corresponding to each of the plurality of multi-view lenses 30. The third light source 103 as will be described below may correspond to one of the plurality of multi-view lenses 30, belong to one of the rows of the light sources 100 included in the light source array 20 and emit light to be provided to the third viewpoint VC among the plurality of viewpoints V, and the third light source 103 may be provided in the plural, each of which is included in each of the plurality of rows, corresponding to each of the plurality of multi-view lenses 30.

In an embodiment, the light source array 20 may include the first light source 101, the second light source 102 and the third light source 103 arranged in a row, side by side. For example, the first light source 101, the second light source 102 and the third light source 103 may be arranged in the second direction X. For example, the first light source 101, the second light source 102 and the third light source 103 may be arranged in sequence in the second direction X. The second light source 102 may be arranged between the first light source 101 and the third light source 103.

The first light source 101, the second light source 102 and the third light source 103 may be configured to emit light to provide an image to different viewpoints among the plurality of viewpoints. For example, the first light source 101 may be configured to emit light to provide an image at the first viewpoint VA among the plurality of viewpoints V. For example, the second light source 102 may be configured to emit light to provide an image at the second viewpoint VB among the plurality of viewpoints V. For example, the third light source 103 may be configured to emit light to provide an image at the third viewpoint VC among the plurality of viewpoints V (see FIG. 2).

The first viewpoint VA, the second viewpoint VB and the third viewpoint VC may be arranged in the second direction X. The second viewpoint VB may be arranged between the first viewpoint VA and the third viewpoint VC.

Referring to FIGS. 2, 5 and 6, a sequence in which the first light source 101, the second light source 102 and the third light source 103 are arranged in the second direction X may be reverse to a sequence in which the first viewpoint VA, the second viewpoint VB and the third viewpoint VC are arranged in an embodiment.

The first viewpoint VA, the second viewpoint VB and the third viewpoint VC may be separated from each other. The first viewpoint VA, the second viewpoint VB and the third viewpoint VC may be separated from each other and arranged in the second direction X in the viewing area.

The multi-view lens 30 may be configured to refract light. The multi-view lens 30 may be configured to refract light emitted from the first light source 101 to proceed toward the first viewpoint VA. The multi-view lens 30 may be configured to refract light emitted from the second light source 102 to proceed toward the second viewpoint VB. The multi-view lens 30 may be configured to refract light emitted from the third light source 103 to proceed toward the third viewpoint VC.

The multi-view lens 30 may be configured to refract light that has entered through the entrance surface 31 to be output through an exit surface 32. The entrance surface 31 may be a surface of the multi-view lens 30, which is adjacent to the plurality of light sources 100. The exit surface 32 may be the other surface of the multi-view lens 30, which is opposite to the entrance surface 31.

For example, the entrance surface 31 may be shaped substantially like a flat panel. For example, the exit surface 32 may have a curved surface swollen in the first direction Z.

The form of the multi-view lens 30 is not, however, limited thereto, and in one or more embodiments, the multi-view lens 30 may have various forms that allow light emitted from each of the first light source 101, the second light source 102 and the third light source 103 to be refracted while passing the multi-view lens 30 to proceed to each corresponding viewpoint VA, VB or VC. As shown in FIG. 2, a direction in which light proceeds to each viewpoint V from each light source 100 may vary depending on the position (e.g., the first point P1 and the second point P2) on the screen S. Hence, the plurality of multi-view lenses 30 may have different shapes or refraction indexes depending on the position at the display apparatus 1 to refract light from the light source 100 to properly proceed to each viewpoint V.

With the aforementioned structure of the plurality of light sources 100 and the multi-view lenses 30, the entire viewing area may have a plurality of viewpoints V to provide different images.

To increase the quality of the image provided at each of the plurality of viewpoints V, it is desirable that the plurality of viewpoints V do not overlap each other, and that the light emitted from each of the plurality of light sources 100 is refracted by the multi-view lens 30 and proceeds only to the corresponding viewpoint V. For example, it is desirable that the light emitted from the first light source 101 and refracted by the multi-view lens 30 proceeds only to the first viewpoint VA rather than the second viewpoint VB and the third viewpoint VC, the light emitted from the second light source 102 and refracted by the multi-view lens 30 proceeds only to the second viewpoint VB rather than the first viewpoint VA and the third viewpoint VC, and the light emitted from the third light source 103 and refracted by the multi-view lens 30 proceeds only to the third viewpoint VC rather than the first viewpoint VA and the second viewpoint VB.

As such, to increase quality of the image provided at each of the plurality of viewpoints V, it may be required to prevent the crosstalk for the light from the first light source 101, the light from the second light source 102 and the light from the third light source 103 not to overlap each other in the viewing area. To prevent the crosstalk, it is desirable to narrow the width of light emitted from each of the plurality of light sources 100 and entering the multi-view lens 30.

An embodiment of the disclosure to reduce the width of light entering the multi-view lens 30 and reduce and/or prevent the crosstalk will now be described in detail by referring to a detailed structure of the light source 100, the entrance surface cover 40, etc.

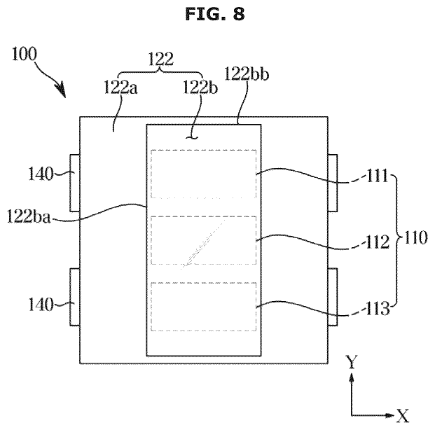

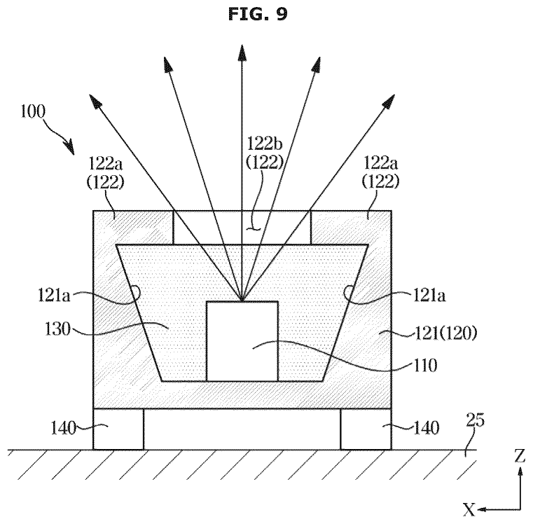

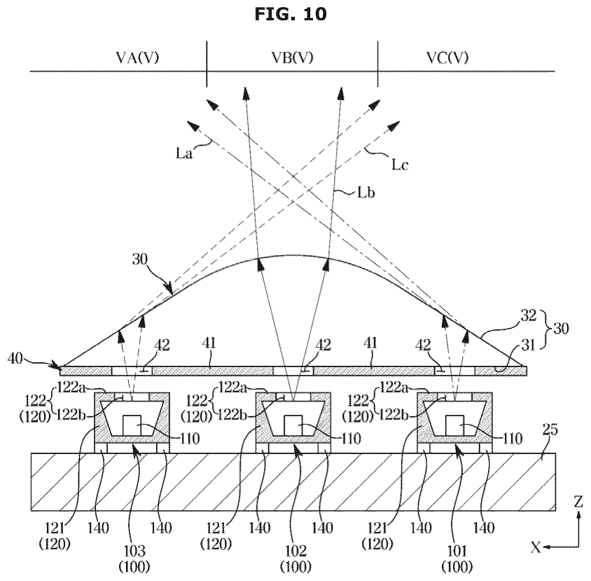

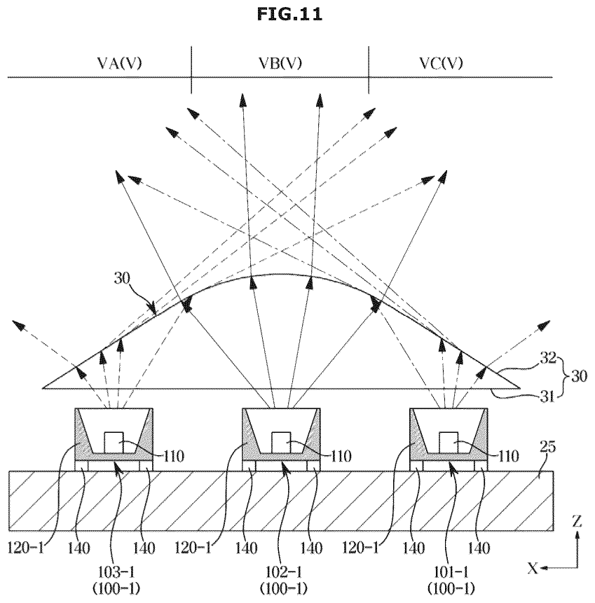

FIG. 7 is a perspective view illustrating a light source of a display apparatus, according to an embodiment of the disclosure. FIG. 8 is a front view illustrating a light source of a display apparatus, according to an embodiment of the disclosure. FIG. 9 is an enlarged cross-sectional view illustrating a light source and a light source substrate of a display apparatus, according to an embodiment of the disclosure. FIG. 10 is an enlarged view of a light source array, an entrance surface cover and a multi-view lens, according to an embodiment of the disclosure. FIG. 11 is an enlarged view of a light source array, an entrance surface cover and a multi-view lens, according to a comparative embodiment.

Referring to FIGS. 7 to 10, the light source 100 of the display apparatus 1 according to an embodiment of the disclosure may include the light emitter 110 and a light source case 120 that accommodates the light emitter 110. The light source case 120 may support the light emitter 110. The light source 100 may be a package type light source in which the light emitter 110 is packaged by the light source case 120.

The light emitter 110 may be configured to emit light when receiving a driving voltage and/or driving current. For example, the light emitter 110 may include an LED.

In an embodiment, the light emitter 110 may include a plurality of light emitters 111, 112 and 113 configured to emit rays of different colors. The one light source 100 may include the plurality of light emitters 111, 112 and 113 configured to emit rays of different colors. The plurality of light emitters 111, 112 and 113 configured to emit rays of different colors may be arranged in the single light source case 120.

For example, the light emitter 110 may include the first light emitter 111 configured to emit a ray of first color, the second light emitter 112 configured to emit a ray of second color, and the third light emitter 113 configured to emit a ray of third color. The first, second, and third colors may be different from one another. For example, the first, second and third colors may be red R, green G and blue B, respectively.

For example, the first light emitter 111, the second light emitter 112 and the third light emitter 113 may receive a driving voltage and/or driving current separately, and emit light separately. The ray of first color emitted from the first light emitter 111, the ray of second color emitted from the second light emitter 112 and the ray of third color emitted from the third light emitter 113 may be combined to form a pixel P of an image that appears on the screen S.

The light source 100 may include an electrode 140 of a conductive material electrically connected to the light source substrate 25. The electrode 140 may be connected to the light emitter 110. The driving voltage and/or driving current may be applied through the electrode 140. The light source 100 may be mounted on the light source substrate 25 as the electrode 140 is connected to the light source substrate 25. The electrode 140 may extend from the light source case 120 to the light source substrate 25.

In an embodiment, the light source 100 may include a light-transparent resin 130 arranged in the light source case 120 and enclosing the light emitter 110. The light-transparent resin 130 may be configured to protect the light emitter 110 and allow light emitted from the light emitter 110 to be transmitted therethrough. The light emitter 110 may be optically transparent or translucent.

For example, the light-transparent resin 130 may include a silicon or epoxy resin material. For example, the light-transparent resin 130 may be formed with melted silicon or epoxy resin injected into the light source case 120 through a nozzle to enclose the light emitter 110 and the injected silicon or epoxy resin hardened.

The light source case 120 may form an accommodation space to accommodate the light emitter 110. The light source case 120 may enclose the light emitter 110. The light source case 120 that encloses the light emitter 110 may have at least one side open to allow the light emitted from the light emitter 110 to pass through. For example, the light source case 120 may have one side open in the first direction Z. For example, the open side of the light source case 120 may be adjacent to the multi-view lens 30.

For example, the light emitter 110 may be arranged on the bottom surface of the accommodation space of the light source case 120. The bottom surface of the accommodation space of the light source case 120 may be opposite to the open side (e.g., the side of a light source slit 122b) of the light source case 120. The light emitter 110 may be mounted on the bottom surface of the accommodation space of the light source case 120.

For example, the light emitter 110 may be arranged roughly in the center of the bottom surface of the accommodation space of the light source case 120.

The light source case 120 may include a case body 121. The case body 121 may support the light emitter 110. The accommodation space for accommodating the light emitter 110 may be formed in the case body 121. The aforementioned light-transparent resin 130 may be arranged in the accommodation space of the case body 121. The case body 121 may enclose the light emitter 110. For example, the case body 121 may enclose the light emitter 110 from a direction parallel to the light source substrate 25, e.g., the direction parallel to the X-Y plane. For example, the case body 121 may enclose the light emitter 110 from a direction different from a direction in which the light emitted from the light emitter 110 proceeds to the multi-view lens 30, e.g., the first direction Z.

In an embodiment, the case body 121 may be formed to block a portion of light emitted from the light emitter 110. For example, the case body 121 may be formed to absorb or reflect the light emitted from the light emitter 110. For example, the case body 121 may include a material of a color that has a high light-absorption rate, such as black, to absorb the light from the light emitter 110 and block procession of the light, or may include a material of a color that has high light reflectivity, such as white, or a metal having high light reflectivity to reflect the light from the light emitter 110 to block procession of the light.

The case body 121 may have a side open to the first direction Z to allow the light emitted from the light emitter 110 to proceed to the multi-view lens 30. The case body 121 may have a side adjacent to the multi-view lens 30 to allow the light emitted from the light emitter 110 to proceed to the multi-view lens 30. For example, the case body 121 may have the form of a box with one side adjacent to the multi-view lens 30 open to at least the first direction Z.

Slanted surfaces 121a may be formed in the case body 121. The slanted surface 121a may be formed on an inner side facing the accommodation space that accommodates the light emitter 110 of the case body 121. The slanted surface 121a may enclose the accommodation space that accommodates the light emitter 110 of the case body 121. The slanted surface 121a may enclose the light-transparent resin 130.

The slanted surface 121a may extend to incline to the outside of the case body 121 as the slanted surface 121a goes toward the open side from the bottom surface of the accommodation space of the case body 121. The slanted surface 121a may be inclined to the first direction Z to widen the width of the accommodation space as the slanted surface 121a in a direction moving toward the open side from the bottom surface of the accommodation space of the case body 121.

For example, the slanted surface 121a may be formed to reflect light. For example, the slanted surface 121a may be coated with a material having high reflectivity. Accordingly, as will be described later, even though the light emitted from the light emitter 110 is restricted by a light blocker 122a, a portion of the light may be reflected by the slanted surface 121a toward the light source slit 122b, thereby preventing excessive reduction of quantity of light.

The light emitted from the light emitter 110 may be radiated in many different directions toward the multi-view lens 30. For example, the light emitted from the light emitter 110 may proceed with the Lambertian distribution. However, when the width or radiation angle of the light emitted from the light emitter 110 is excessively wide, a crosstalk phenomenon may occur where rays emitted from different light sources 100, e.g., the first light source 101, the second light source 102 and the third light source 103, are transmitted and refracted from the multi-view lens 30, proceed toward different viewpoints V rather than their corresponding viewpoints V and overlap each other. When there is the crosstalk, the different viewpoints V may not be clearly separated, causing deterioration of image quality.

In an embodiment of the disclosure, to limit the width of light emitted and proceeding from the light emitter 110 to prevent the crosstalk, each of the plurality of light sources 100 may include a slit cover 122.

The slit cover 122 may be arranged between the light emitter 110 and the multi-view lens 30. The slit cover 122 may be arranged in front of the light emitter 110 in the first direction Z. The slit cover 122 may limit the width of light emitted from the light emitter 110 and entering the multi-view lens 30 by covering a portion of the light emitter 110 between the light emitter 110 and the multi-view lens 30.

For example, the slit cover 122 may be arranged on a side of the light source case 120 that faces the multi-view lens 30. The slit cover 122 may be arranged on a side of the case body 121 that faces the multi-view lens 30. The slit cover 122 may be a component included in the light source case 120. For example, the slit cover 122 may be integrally formed with the case body 121, but the disclosure is not limited thereto.

For example, the slit cover 122 may be arranged on a side of the light-transparent resin 130 that faces the multi-view lens 30. The slit cover 122 may be arranged on the side of the light-transparent resin 130 that faces the multi-view lens 30 to cover a portion of the light-transparent resin 130.

The slit cover 122 may include the light blocker 122a. The light blocker 122a may be configured to block a portion of light emitted from the light emitter 110. The slit cover 122 may limit the width of light entering the multi-view lens 30 by blocking a portion of the light emitted from the light emitter 110.

In an embodiment, the light blocker 122a may have a material with a high light-absorption rate to absorb a portion of the light emitted from the light emitter 110. For example, the light blocker 122a may come in black to absorb a portion of the light emitted from the light emitter 110. For example, the light blocker 122a may include a black coating layer. The black coating layer may be formed by being coated in various coating methods such as printing or sputtering black paint on one side of the light emitter 110 that faces the multi-view lens 30. For example, the black coating layer may be formed by being coated on one side of the light source case 120 or the light-transparent resin 130 that faces the multi-view lens 30.

In an embodiment, the light blocker 122a may include a material with high light reflectivity to reflect a portion of the light emitted from the light emitter 110 back to the light emitter 110 or toward the inside of the light source case 120. For example, the light blocker 122a may include a reflective layer formed by coating the material with a high light reflectivity. The reflective layer may be formed by being coated in various coating methods such as printing or sputtering a white paint or a metal with high reflectivity on one side of the light emitter 110 that faces the multi-view lens 30. For example, the reflective layer may be formed by being coated on one side of the light source case 120 or the light-transparent resin 130 that faces the multi-view lens 30.

The slit cover 122 may include the light source slit 122b configured to allow the light to pass through. The light source slit 122b may be formed such that a portion of the slit cover 122 is penetrated to allow light to pass through.

The light source slit 122b may be arranged in the first direction Z, i.e., in the front. For example, the light source slit 122b and the light emitter 110 may be arranged in the first direction Z in parallel. For example, the center of the light source slit 122b and the center of the light emitter 110 may be arranged in a line in the first direction Z. For example, the center of the light source slit 122b and the center of the light emitter 110 may be arranged in a straight line that extends in substantially the first direction Z.

The light blocker 122a may be arranged around the light source slit 122b. The light source slit 122b may be arranged in an area surrounded by the light blocker 122a. The light source slit 122b may be defined in a portion of the slit cover 122 that is penetrated, and the light blocker 122a may be defined in another portion of the slit cover 122 that is not penetrated.

For example, as shown in FIGS. 7 and 8, the light source slit 122b may have the form of a rectangle with four sides. The light blocker 122a may be provided to surround the four sides of the light source slit 122b. In one or more embodiments, however, the form of the light source slit 122b is not limited to the rectangular shape.

For example, the light source slit 122b may be arranged substantially in the middle of the slit cover 122.

The light source slit 122b may be arranged so that the light emitted from the light emitter 110 is transmitted within a predetermined width. A portion of the light emitted from the light emitter 110 may be blocked by the light blocker 122a, and a non-blocked portion of the light may pass through the light source slit 122b and enter the multi-view lens 30. The width of the light emitted from the light emitter 110 and entering the multi-view lens 30 may be limited to a certain width or less by the light blocker 122a and the light source slit 122b. The width of light that passes through the light source slit 122b and exits from the light source 100 may be determined according to the width of the light source slit 122b. A radiation angle of the light that passes through the light source slit 122b and exits from the light source 100 may be determined according to the width of the light source slit 122b.

To limit the light emitted from the light emitter 110 to a predetermined width or less, the light blocker 122a may cover a portion of the internal space of the light source case 120 from the first direction Z. Hence, the width of the light source slit 122b arranged within the light blocker 122a may be smaller than the width of the internal space of the light source case 120 that accommodates the light emitter 110.

For example, the width of the light source slit 122b may be defined to be a width in a minor side of the light source slit 122b. For example, the width of the light source slit 122b may be defined to be a width in a short side 122bb of the light source slit 122b. For example, the width of the light source slit 122b may be defined to be a width in the second direction X of the light source slit 122b.

For example, the light source slit 122b may have a width of about 0.2 mm to 0.5 mm. The width of the light source slit 122b is not, however, limited thereto, and in one or more embodiments, the width of the light source slit 122b may vary depending on the distance between the multi-view lens 30 and the light source 100, the distance between neighboring light sources 100 (e.g., the first light source 101 and the second light source 102 or the second light source 102 and the third light source 103) among the plurality of light sources 100, the number of viewpoints V, etc.

In an embodiment, the light source slit 122b may extend in one direction. For example, the light source slit 122b may include long sides 122ba and short sides 122bb, and the one direction in which the light source slit 122b extends may be defined to be a direction in which the long sides 122ba extend. For example, the long side 122ba and the short side 122bb of the light source slit 122b may be perpendicular to each other.

The direction in which the light source slit 122b extends may be perpendicular to the direction in which the plurality of light sources 100 are arranged. For example, the direction in which the light source slit 122b extends may be perpendicular to the direction in which the first light source 101, the second light source 102 and the third light source 103 are arranged. For example, the direction in which the long side 122ba of the light source slit 122b extends may be perpendicular to the direction in which the first light source 101, the second light source 102 and the third light source 103 are arranged. For example, the direction in which the short side 122bb of the light source slit 122b extends may be parallel to the direction in which the first light source 101, the second light source 102 and the third light source 103 are arranged.

As such, as the direction of the short side 122bb of the light source slit 122b is parallel to the direction in which the first light source 101, the second light source 102 and the third light source 103 are arranged, the width of light that passes through the light source slit 122b may be limited in the direction in which the first light source 101, the second light source 102 and the third light source 103 are arranged, i.e., the second direction X. Accordingly, the crosstalk between the light emitted from the first light source 101, the light emitted from the second light source 102 and the light emitted from the third light source 103 may be efficiently prevented. Also, as the light source slit 122b extends longer in the direction perpendicular to the direction in which the first light source 101, the second light source 102 and the third light source 103 are arranged, excessive limitation on the quantity of light to enter the multi-view lens 30 may be prevented.

The direction in which the light source slit 122b extends may be perpendicular to the direction in which the plurality of viewpoints V are arranged. For example, the direction in which the light source slit 122b extends may be perpendicular to the direction in which the first viewpoint VA, the second viewpoint VB and the third viewpoint VC are arranged. For example, the direction in which the long side 122ba of the light source slit 122b extends may be perpendicular to the direction in which the first viewpoint VA, the second viewpoint VB and the third viewpoint VC are arranged. For example, the direction in which the short side 122bb of the light source slit 122b extends may be parallel to the direction in which the first viewpoint VA, the second viewpoint VB and the third viewpoint VC are arranged.

Similar to what is described above, as the direction of the short side 122bb of the light source slit 122b is parallel to the direction in which the plurality of viewpoints V are arranged, the width of light that passes through the light source slit 122b may be limited in the direction in which the plurality of viewpoints V are arranged, e.g., the second direction X. This may prevent overlapping between different viewpoints V more efficiently. Also, as the light source slit 122b extends longer in the direction perpendicular to the direction in which the plurality of viewpoints V are arranged, excessive limitation on the quantity of light to enter the multi-view lens 30 may be prevented.

The direction in which the light source slit 122b extends may be perpendicular to a direction in which the plurality of multi-view lenses 30 are arranged, e.g., the second direction X (see FIGS. 5 and 6). For example, the direction in which the long side 122ba of the light source slit 122b extends may be perpendicular to the direction in which the plurality of multi-view lenses 30 are arranged. For example, the direction in which the short side 122bb of the light source slit 122b extends may be parallel to the direction in which the plurality of multi-view lenses 30 are arranged.

As described above, the light emitter 110 may include a plurality of light emitters 110 configured to emit rays of different colors. For example, the plurality of light emitters 110 may include the first light emitter 111, the second light emitter 112, and the third light emitter 113. The plurality of light emitters 110 may be arranged side by side in one direction, e.g., the third direction Y. The direction in which the light source slit 122b extends may be parallel to the direction in which the plurality of light emitters 110 are arranged. For example, the direction in which the long side 122ba of the light source slit 122b extends may be parallel to the direction in which the plurality of light emitters 110 are arranged. For example, the direction in which the short side 122bb of the light source slit 122b extends may be substantially perpendicular to the direction in which the plurality of light emitters 110 are arranged.

As the direction in which the light source slit 122b extends is parallel to the direction in which the plurality of light emitters 110 extend, one of the plurality of light emitters 110, e.g., the first light emitter 111 or the third light emitter 113 located on either side, may be prevented from being hidden by the light blocker 122a of the slit cover 122, and the width of light to exit from the light source 100 may be efficiently limited by narrowing the width of the light source slit 122b.

It is possible to limit the width of light emitted from the light emitter 110 and entering the multi-view lens 30 to a certain width or less by using the light source slit 122b with the aforementioned structure, and the width of the light source slit 122b or the certain width may be properly set according to various design factors such as the number of separate viewpoints V, the width of each viewpoint V, the refraction index of the multi-view lens 30, a distance between the multi-view lens 30 and the light source 100, a quantity of light to be provided to each viewpoint V, etc.

In an embodiment of the disclosure, along with the structure of the slit cover 122 including the light source slit 122b, the display apparatus 1 may further include the entrance surface cover 40 to limit the width of light entering the multi-view lens 30 more efficiently.

The entrance surface cover 40 may be arranged between the plurality of light sources 100 and the multi-view lens 30. The entrance surface cover 40 may be arranged in front of the plurality of light sources 100 in the first direction Z. The entrance surface cover 40 may cover a portion of the entrance surface 31 of the multi-view lens 30 between the plurality of light sources 100 and the multi-view lens 30 to limit the width of light entering the multi-view lens 30.

In an embodiment, the entrance surface cover 40 may be arranged on the entrance surface 31 of the multi-view lens 30. The entrance surface cover 40 may contact the entrance surface 31 of the multi-view lens 30. For example, the entrance surface cover 40 may be attached to the entrance surface 31 of the multi-view lens 30. For example, the entrance surface cover 40 may be coated on the entrance surface 31 of the multi-view lens 30.

The entrance surface cover 40 may include a light absorber 41. The light absorber 41 may be configured to absorb a portion of light that exits from the plurality of light sources 100. The light absorber 41 may be configured to absorb a portion of light that exits from the light source slit 122b of each of the plurality of light sources 100. The light absorber 41 may limit the width of light entering the multi-view lens 30 by absorbing a portion of light that has passed through the light source slit 122b.

In an embodiment, the light absorber 41 may include a material with a high light-absorption rate to absorb a portion of the light that passes through the light source slit 122b. For example, the light absorber 41 may come in black to absorb a portion of light that has passed through the light source slit 122b. For example, the light absorber 41 may be formed by being coated in various coating methods such as printing or sputtering black paint on the entrance surface 31 of the multi-view lens 30.

Especially, in an embodiment where the light blocker 122a of the slit cover 122 includes a material with high reflectivity (a material that comes in white, a metal, etc.), light entering from outside of the display apparatus 1 (from the forward direction in particular) is absorbed by the light absorber 41, thereby efficiently preventing a phenomenon in which the screen glitters.

The entrance surface cover 40 may include a lens slit 42 configured to allow light to pass through. The lens slit 42 may have the form in which a portion of the entrance surface cover 40 is penetrated to allow light to pass through. The lens slit 42 may be formed to allow a portion of light emitted from the light emitter 110 and having passed through the light source slit 122b to pass through.

The lens slit 42 may be provided in the plural. The plurality of lens slits 42 may be provided to correspond to the plurality of light sources 100. The light absorber 41 may be arranged in areas between the plurality of lens slits 42.

The plurality of lens slits 42 may be arranged side by side. For example, the plurality of lens slits 42 may be arranged in a direction parallel to the direction in which the plurality of light sources 100, e.g., the first light source 101, the second light source 102 and the third light source 103, are arranged. For example, the plurality of lens slits 42 may be arranged in a direction parallel to the direction in which the plurality of viewpoints V are arranged. For example, the plurality of lens slits 42 may be arranged in a direction parallel to the direction in which the plurality of multi-view lenses 30 are arranged. For example, the plurality of lens slits 42 may be arranged in a direction substantially parallel to the second direction X.

The plurality of lens slits 42 may be arranged in the first direction Z, i.e., in the forward direction. For example, each of the plurality of lens slits 42 may be arranged in parallel with a corresponding one of the plurality of light sources 100 in the first direction Z.

For example, when the lens slit 42 corresponding to the first light source 101 is called a first lens slit 42, the first lens slit 42 may be configured to allow at least a portion of light La that has passed through the light source slit 122b of the first light source 101 to pass through. In an embodiment, the light emitter 110 of the first light source 101, the light source slit 122b of the first light source 101 and the first lens slit 42 may be arranged in parallel with each other in the first direction Z. In an embodiment, the center of the light emitter 110 of the first light source 101, the center of the light source slit 122b of the first light source 101 and the center of the first lens slit 42 may be arranged in a line in the first direction Z. In an embodiment, the center of the light emitter 110 of the first light source 101, the center of the light source slit 122b of the first light source 101 and the center of the first lens slit 42 may be arranged in a straight line that extends substantially in the first direction Z.

For example, when the lens slit 42 corresponding to the second light source 102 is called a second lens slit 42, the second lens slit 42 may be configured to allow at least a portion of light Lb that has passed through the light source slit 122b of the second light source 102 to pass through. In an embodiment, the light emitter 110 of the second light source 102, the light source slit 122b of the second light source 102 and the second lens slit 42 may be arranged in parallel with each other in the first direction Z. In an embodiment, the center of the light emitter 110 of the second light source 102, the center of the light source slit 122b of the second light source 102 and the center of the second lens slit 42 may be arranged in a line in the first direction Z. In an embodiment, the center of the light emitter 110 of the second light source 102, the center of the light source slit 122b of the second light source 102 and the center of the second lens slit 42 may be arranged in a straight line that extends in substantially the first direction Z.

For example, when the lens slit 42 corresponding to the third light source 103 is called a third lens slit 42, the third lens slit 42 may be configured to allow at least a portion of light Lc that has passed through the light source slit 122b of the third light source 103 to pass through. In an embodiment, the light emitter 110 of the third light source 103, the light source slit 122b of the third light source 103 and the third lens slit 42 may be arranged in parallel with each other in the first direction Z. In an embodiment, the center of the light emitter 110 of the third light source 103, the center of the light source slit 122b of the third light source 103 and the center of the third lens slit 42 may be arranged in a line in the first direction Z. In an embodiment, the center of the light emitter 110 of the third light source 103, the center of the light source slit 122b of the third light source 103 and the center of the third lens slit 42 may be arranged in a straight line that extends in substantially the first direction Z.

The lens slit 42 may be arranged for the light that has passed through the light source slit 122b to pass through within a certain width and enter the multi-view lens 30. A portion of the light that has passed through the light source slit 122b may be blocked by the light absorber 41 of the entrance surface cover 40, and a non-blocked portion of the light may pass through the lens slit 42 and enter the multi-view lens 30. As described above, the width of light emitted from the light emitter 110 may be limited by the light blocker 122a and the light source slit 122b of the slit cover 122 for the first time, and the width of light having passed through the light source slit 122b and entering the multi-view lens 30 may be limited for the second time by the structure of the light absorber 41 and the lens slit 42. The width of the light entering the multi-view lens 30 may be determined by the width of the lens slit 42. An angle of the light entering the multi-view lens 30 may be determined by the width of the lens slit 42.

The width of the lens slit 42 may be defined to be the width of a short side of the lens slit 42. For example, the width of the lens slit 42 may be defined in a direction parallel to the direction of the width of the light source slit 122b, i.e., the direction of the short side 122bb of the light source slit 122b. For example, the width of the lens slit 42 may be defined to be the width of the lens slit 42 in the second direction X.

The width of the lens slit 42 may be equal to or smaller than the light source slit 122b. In an embodiment, as shown in FIG. 10, the width of the lens slit 42 may be substantially equal to the width of the light source slit 122b. When the width of the lens slit 42 is larger than the width of the light source slit 122b, the effect of limiting light by the entrance surface cover 40 is expected to be of little actual benefit.

In an embodiment, the lens slit 42 may extend in one direction. For example, the lens slit 42 may have long sides and short sides, and the one direction in which the lens slit 42 extends may be defined as a direction in which the long sides extend, and a width direction of the lens slit 42 may be defined as a direction in which the short sides extend. For example, the long side and the short side of the lens slit 42 may be perpendicular to each other.

The direction in which the lens slit 42 extends may be parallel to a direction in which the light source slit 122b extends. The direction in which the lens slit 42 extends may be parallel to a direction in which the long side 122ba of the light source slit 122b extends. The long side of the lens slit 42 may be parallel to the long side 122ba of the light source slit 122b. The short side of the lens slit 42 may be parallel to the short side 122bb of the light source slit 122b.

The direction in which the lens slit 42 extends may be perpendicular to the direction in which the plurality of light sources 100 are arranged. For example, the direction in which the lens slit 42 extends may be perpendicular to the direction in which the first light source 101, the second light source 102 and the third light source 103 are arranged. For example, the direction in which the long side of the lens slit 42 extends may be perpendicular to the direction in which the first light source 101, the second light source 102 and the third light source 103 are arranged. For example, the direction in which the short side of the lens slit 42 extends may be parallel to the direction in which the first light source 101, the second light source 102 and the third light source 103 are arranged.

As such, as the direction of the short side of the lens slit 42 is parallel to the direction in which the first light source 101, the second light source 102 and the third light source 103 are arranged, the width of light that passes through the lens slit 42 and enters the multi-view lens 30 may be limited in the direction in which the first light source 101, the second light source 102 and the third light source 103 are arranged, i.e., the second direction X. Accordingly, the crosstalk between the light emitted from the first light source 101, the light emitted from the second light source 102 and the light emitted from the third light source 103 may be efficiently prevented. Also, as the lens slit 42 extends longer in the direction perpendicular to the direction in which the first light source 101, the second light source 102 and the third light source 103 are arranged, excessive limitation on the quantity of light to enter the multi-view lens 30 may be prevented.

The direction in which the lens slit 42 extends may be perpendicular to the direction in which the plurality of viewpoints V are arranged. For example, the direction in which the lens slit 42 extends may be perpendicular to the direction in which the first viewpoint VA, the second viewpoint VB and the third viewpoint VC are arranged. For example, the direction in which the long side of the lens slit 42 extends may be perpendicular to the direction in which the first viewpoint VA, the second viewpoint VB and the third viewpoint VC are arranged. For example, the direction in which the short side of the lens slit 42 extends may be parallel to the direction in which the first viewpoint VA, the second viewpoint VB and the third viewpoint VC are arranged.

Similar to what is described above, as the direction of the short side of the lens slit 42 is parallel to the direction in which the plurality of viewpoints V are arranged, the width of light that passes through the lens slit 42 may be limited in the direction in which the plurality of viewpoints V are arranged, e.g., the second direction X. This may prevent overlapping between different viewpoints V more efficiently. Also, as the lens slit 42 extends longer in the direction perpendicular to the direction in which the plurality of viewpoints V are arranged, excessive limitation on the quantity of light to enter the multi-view lens 30 may be prevented.

The direction in which the lens slit 42 extends may be perpendicular to a direction in which the plurality of multi-view lenses 30 are arranged, e.g., the second direction X (see FIGS. 5 and 6). For example, the direction in which the long side of the lens slit 42 extends may be perpendicular to the direction in which the plurality of multi-view lenses 30 are arranged. For example, the direction in which the short side of the light source slit 122b extends may be parallel to the direction in which the plurality of multi-view lenses 30 are arranged.

The direction in which the lens slit 42 extends may be parallel to the direction in which the plurality of light emitters 110 (e.g., the first light emitter 111, the second light emitter 112, and the third light emitter 113) are arranged. For example, the direction in which the long side 122ba of the lens slit 42 extends may be parallel to the direction in which the plurality of light emitters 110 are arranged. For example, the direction in which the short side of the lens slit 42 extends may be substantially perpendicular to the direction in which the plurality of light emitters 110 are arranged.

It is possible to limit the width of light having passed through both the light source slit 122b and the lens slit 42 and entering the multi-view lens 30 to a certain width or less by using the lens slit 42 with the aforementioned structure, and the width of the lens slit 42 or the certain width may be properly set according to various design factors such as the number of separate viewpoints V, the width of each viewpoint V, the refraction index of the multi-view lens 30, a distance between the multi-view lens 30 and the light source 100, the quantity of light to be provided to each viewpoint V, etc.

In an embodiment, the entrance surface cover 40 may be integrally formed and arranged on the entrance surface 31 of the multi-view lens 30 (see FIG. 6). Alternatively, in an embodiment, the entrance surface cover 40 may be formed in the plural, and each entrance surface cover 40 may be arranged on the entrance surface 31 of each of the plurality of multi-view lenses 30.

As described above, the display apparatus 1 including the slit cover 122 and the entrance surface cover 40 may limit the width of light emitted from the light emitter 110 and entering the multi-view lens 30 to a certain width or less. Accordingly, occurrences of the crosstalk between rays emitted from the plurality of light sources 100 may be efficiently reduced and/or prevented. For example, as shown in FIG. 10, the light La emitted from the first light source 101 may pass the light source slit 122b of the slit cover 122 and the lens slit 42 of the entrance surface cover 40 in sequence, enter the multi-view lens 30 with a limited width, and be refracted by the multi-view lens 30 to proceed toward the first viewpoint VA. Furthermore, as shown in FIG. 10, the light Lb emitted from the second light source 102 may pass the light source slit 122b of the slit cover 122 and the lens slit 42 of the entrance surface cover 40 in sequence, enter the multi-view lens 30 with a limited width, and be refracted by the multi-view lens 30 to proceed toward the second viewpoint VB. As shown in FIG. 10, the light Lc emitted from the third light source 103 may pass the light source slit 122b of the slit cover 122 and the lens slit 42 of the entrance surface cover 40 in sequence, enter the multi-view lens 30 with a limited width, and be refracted by the multi-view lens 30 to proceed toward the third viewpoint VC. In this procedure, the light La emitted from the first light source 101 may not reach the second viewpoint VB or the third viewpoint VC; the light Lb emitted from the second light source 102 may not reach the first viewpoint VA or the third viewpoint VC; the light Lc emitted from the third light source 103 may not reach the first viewpoint VA or the second viewpoint VB. The rays La, Lb and Lc emitted from the light sources 101, 102 and 13 do not overlap in the viewing area, thereby preventing an occurrence of the crosstalk, reducing noise of the image, and enhancing image quality. Furthermore, as the crosstalk is reduced/prevented, it is possible to design an increasing number of viewpoints V to be provided by the display apparatus 1.

Referring to FIG. 11, an embodiment to be compared with the embodiment of the disclosure as described above with reference to FIGS. 1 to 10 will now be described.

Referring to FIG. 11, in the comparative embodiment, each of a plurality of light sources 100-1 may include a light emitter 110 and a light source case 120-1 that accommodates the light emitter 110. The light source case 120-1 may have a form with one side open to the multi-view lens 30. Unlike in the embodiment described with reference to FIGS. 1 to 10, the plurality of light sources 100-1 are not equipped with the slit cover for limiting the width of light emitted from the light emitter 110 in the comparative embodiment of FIG. 11. Furthermore, unlike in the embodiment described with reference to FIGS. 1 to 10, there is no entrance surface cover arranged between the multi-view lens 30 and the plurality of light sources 100-1 to limit the width of light entering the multi-view lens 30 in the comparative embodiment of FIG. 11.

With this structure, in the comparative embodiment, light emitted from each of the plurality of light sources 100-1 may proceed with a relatively wide width and enter the multi-view lens 30. Then, there are chances that the rays refracted by the multi-view lens 30 each proceed not only to the corresponding viewpoint V but also to other viewpoints V, and in this case, the rays may overlap in the viewing area so that the crosstalk occurs. For example, as shown in FIG. 11, a portion of the light emitted from the first light source 101-1 may enter not only the first viewpoint VA but also the second viewpoint VB or the third viewpoint VC, a portion of the light emitted from the second light source 102-1 may enter not only the second viewpoint VB but also the first viewpoint VA or the third viewpoint VC, and a portion of the light emitted from the third light source 103-1 may enter not only the third viewpoint VC but also the first viewpoint VA or the second viewpoint VB.

On the other hand, as shown in FIG. 10, in an embodiment of the disclosure, by using the slit cover 122 and the entrance surface cover 40 to limit the width of light entering the multi-view lens 30, the crosstalk may be reduced and/or prevented more efficiently.

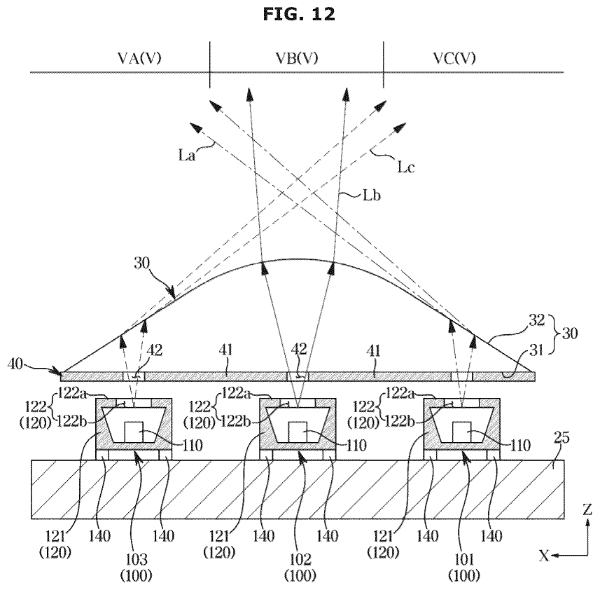

FIG. 12 is an enlarged view of a light source array, an entrance surface cover and a multi-view lens, according to an embodiment of the disclosure.

In describing an embodiment of the disclosure with reference to FIG. 12, the same components as in the embodiments described with reference to FIGS. 1 to 10 may have the same reference numerals, so the detailed description thereof will not be repeated.

Referring to FIG. 12, the entrance surface cover 40 of the display apparatus 1 according to an embodiment of the disclosure may include the lens slit 42 having a width narrower than the width of the light source slit 122b of the slit cover 122. The width of the lens slit 42 may be smaller than the width of the light source slit 122b, and the width of the lens slit 42 and the width of the light source slit 122b may be defined as widths in the corresponding direction.

The width of the light source slit 122b may be defined as a width in a short side of the light source slit 122b, i.e., a width in a direction of the short side 122bb. The width of the light source slit 122b may be defined as the width of the light source slit 122b in a direction in which the plurality of light sources 100, e.g., the first light source 101, the second light source 102 and the third light source 103, are arranged. The width of the light source slit 122b may be defined as the width of the light source slit 122b in a direction in which the plurality of viewpoints V, e.g., the first viewpoint VA, the second viewpoint VB and the third viewpoint VC, are arranged. The width of the light source slit 122b may be defined as the width of the light source slit 122b in a direction in which the plurality of multi-view lenses 30 are arranged. The width of the light source slit 122b may be defined as the width of the light source slit 122b in a direction perpendicular to a direction in which the plurality of light emitters 110, e.g., the first light emitter 111, the second light emitter 112 and the third light emitter 113, are arranged. The width of the light source slit 122b may be defined to be a width in the second direction X of the light source slit 122b.

Likewise, the width of the lens slit 42 may be defined to be the width of a short side of the lens slit 42. The width of the lens slit 42 may be defined to be the width of the lens slit 42 in a direction in which the plurality of light sources 100, e.g., the first light source 101, the second light source 102 and the third light source 103, are arranged. The width of the lens slit 42 may be defined to be the width of the lens slit 42 in a direction in which the plurality of viewpoints V, e.g., the first viewpoint VA, the second viewpoint VB and the third viewpoint VC, are arranged. The width of the lens slit 42 may be defined to be the width of the lens slit 42 in a direction in which the plurality of multi-view lenses 30 are arranged. The width of the lens slit 42 may be defined to be the width of the lens slit 42 in a direction perpendicular to a direction in which the plurality of light emitters 110, e.g., the first light emitter 111, the second light emitter 112 and the third light emitter 113, are arranged. The width of the lens slit 42 may be defined to be the width of the lens slit 42 in the second direction X.

With this structure, the entrance surface cover 40 may limit the width of light having passed the light source slit 122b and entering the multi-view lens 30 through the lens slit 42 more efficiently.

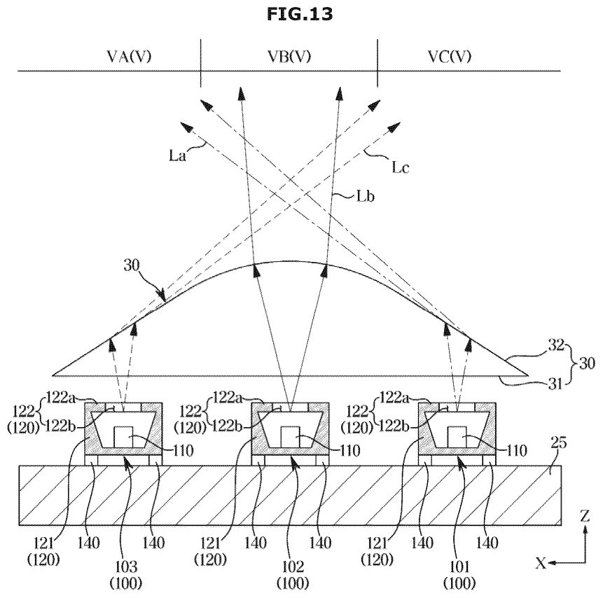

FIG. 13 is an enlarged view of a light source array and a multi-view lens of a display apparatus, according to an embodiment of the disclosure.

In describing an embodiment of the disclosure with reference to FIG. 13, the same components as in the embodiments described with reference to FIGS. 1 to 10 may have the same reference numerals, so the detailed description thereof will not be repeated.

Referring to FIG. 13, the display apparatus 1 according to an embodiment of the disclosure may include the slit cover 122 for covering a portion of the light emitter 110, and the slit cover 122 may include the light source slit 122b configured to allow the light emitted from the light emitter 110 to pass through within a certain width. However, unlike in the aforementioned embodiments, the display apparatus 1 according to an embodiment may not include the entrance surface cover. In other words, in an embodiment, no entrance surface cover is arranged on the entrance surface 31 of the multi-view lens 30, so the rays having passed through the light source slit 122b may directly enter the multi-view lens 30.

Even in this case, the width of the light source slit 122b, the distance between the light source 100 and the multi-view lens 30, the distance between the plurality of light sources 100, the number of the light sources 100 and the viewpoints V, etc., may be properly designed to reduce and/or prevent an occurrence of the crosstalk such as overlapping of rays refracted by the multi-view lens 30 in the viewing area.

According to an embodiment of the disclosure, a display apparatus configured to provide multiple different images at multiple viewpoints may include a first light source configured to emit light to provide an image at a first viewpoint among the multiple viewpoints, a second light source arranged side by side with the first light source and configured to emit light to provide an image at a second viewpoint different from the first viewpoint among the multiple viewpoints, and a multi-view lens configured to refract the light emitted from the first light source to proceed toward the first viewpoint and refract the light emitted from the second light source to proceed toward the second viewpoint. The first light source and the second light source may each include a light emitter and a slit cover covering a portion of the light emitter between the light emitter and the multi-view lens, wherein the slit cover includes a light source slit configured to allow the light emitted from the light emitter to pass through within a predetermined width.

A direction in which the light source slit of the slit cover included in each of the first light source and the second light source extends may be perpendicular to a direction in which the first light source and the second light source are arranged.

A direction in which the light source slit of the slit cover included in each of the first light source and the second light source extends may be perpendicular to a direction in which the first viewpoint and the second viewpoint are arranged.

The multi-view lens may include a plurality of multi-view lenses. A direction in which the light source slit of the slit cover included in each of the first light source and the second light source extends may be perpendicular to a direction in which the plurality of multi-view lenses are arranged.

The light emitter included in each of the first light source and the second light source may include a first light emitter configured to emit light of first color, a second light emitter configured to emit light of second color which is different from the first color, and a third light emitter configured to emit light of third color which is different from the first color and the second color. A direction in which the first light emitter, the second light emitter and the third light emitter are arranged may be in parallel with a direction in which the light source slit of the slit cover included in each of the first light source and the second light source extends.

The display apparatus may further include an entrance surface cover arranged between the slit cover and the multi-view lens, and having a lens slit configured to allow light having passed through the light source slit to pass through within a predetermined width and enter the multi-view lens.

Width of the lens slit may be equal to or smaller than width of the light source slit.

The entrance surface cover may be arranged on an entrance surface of the multi-view lens which is adjacent to the first light source and the second light source.

The entrance surface cover may include a light absorber coated on the entrance surface of the multi-view lens which is adjacent to the first light source and the second light source.

The lens slit may include a first lens slit configured to allow at least a portion of light having passed through the light source slit of the first light source to pass through, and a second lens slit configured to allow at least a portion of light having passed through the light source slit of the second light source to pass through. A center of the light emitter of the first light source, a center of the light source slit of the first light source and a center of the first lens slit may be arranged in a line. A center of the light emitter of the second light source, a center of the light source slit of the second light source and a center of the second lens slit may be arranged in a line.

Each of the first light source and the second light source may further include a light source case accommodating the light emitter. The slit cover may be arranged on one side of the light source case toward the multi-view lens.

Each of the first light source and the second light source may further include a light-transparent resin arranged in the light source case and enclosing the light emitter. The slit cover may cover a portion of the light-transparent resin on one side of the light-transparent resin toward the multi-view lens.

The slit cover may include a light blocker placed around the light source slit and configured to block a portion of light emitted from the light emitter.

The light blocker may include a black coating layer configured to absorb a portion of light emitted from the light emitter.

The light blocker may include a reflective layer configured to reflect a portion of light emitted from the light emitter toward the light emitter.

According to an embodiment of the disclosure, a display apparatus may include a plurality of light sources arranged side by side with one another to emit light forward to provide multiple different images at multiple viewpoints, and a multi-view lens configured to refract the light emitted from the plurality of light sources to proceed to a corresponding viewpoint among the multiple viewpoints. Each of the plurality of light sources may include a light emitter and a light source case accommodating the light emitter. The light source case may include a light source slit arranged between the light emitter and the multi-view lens and configured to allow the light emitted from the light emitter to pass through within a predetermined width, and a light blocker arranged around the light source slit and configured to block a portion of the light emitted from the light emitter.

Width of the light source slit may be smaller than width of an internal space of the light source case in which the light emitter is accommodated.

The light blocker may be formed by coating a material configured to absorb or reflect a portion of light emitted from the light emitter.

The light source slit may have a rectangle shape having four sides. The light blocker may enclose the four sides of the light source slit.

According to an embodiment of the disclosure, a display apparatus may include a plurality of light sources arranged side by side with one another and configured to emit light forward to provide multiple different images at multiple viewpoints, and a multi-view lens configured to refract the light emitted from the plurality of light sources to proceed to a corresponding viewpoint among the multiple viewpoints. Each of the plurality of light sources may include a light emitter and a slit cover covering a portion of the light emitter between the light emitter and the multi-view lens, wherein the slit cover includes a light source slit configured to allow the light emitted from the light emitter to pass through within a predetermined width.

According to the disclosure, a display apparatus may include a plurality of light sources configured to emit light to provide different images and a multi-view lens arranged in front of the plurality of light sources to provide different images at multiple viewpoints.

According to the disclosure, the plurality of light sources may include a slit cover configured to limit width of light emitted from the light emitter to narrow the width of light entering the multi-view lens.

According to the disclosure, the number of different viewpoints formed in a viewing area may increase as the width of light entering the multi-view lens is narrowed by the slit cover.

According to the disclosure, the width of light entering the multi-view lens may be narrowed by the slit cover so that the crosstalk is reduced and/or prevented, thereby reducing noise of the image and enhancing image quality.

According to the disclosure, an entrance surface cover arranged on an entrance surface of the multi-view lens to limit the width of light emitted from the light source and entering the multi-view lens is included to narrow the width of light entering the multi-view lens.

According to the disclosure, the number of different viewpoints formed in a viewing area may increase as the width of light entering the multi-view lens is narrowed by the entrance surface cover.

According to the disclosure, the width of light entering the multi-view lens may be narrowed by the entrance surface cover so that the crosstalk is reduced and/or prevented, thereby reducing noise of the image and enhancing image quality.

Effects according to technical ideas of the disclosure are not limited to what are described above, and throughout the specification it will be clearly appreciated by those of ordinary skill in the art that there may be other effects unmentioned.

One or more embodiments of the disclosure have been described above, but a person of ordinary skill in the art will understand and appreciate that various modifications can be made without departing from the scope of the disclosure. Thus, it will be apparent to those of ordinary skill in the art that the true scope of technical protection is only defined by the following claims.

What is claimed is:

1. A display apparatus comprising:
a first light source configured to emit light visible from a first viewpoint;
a second light source arranged in a row with the first light source in a first direction and configured to emit light visible from a second viewpoint different from the first viewpoint; and
at least one multi-view lens configured to refract the light emitted from the first light source to proceed toward the first viewpoint and to refract the light emitted from the second light source to proceed toward the second viewpoint,
wherein each of the first light source and the second light source comprises:
a light emitter; and
a slit cover covering a portion of the light emitter between the light emitter and the at least one multi-view lens, wherein the slit cover comprises a light source slit having a first width and is configured to allow the light emitted from the light emitter to pass through the light source slit.

2. The display apparatus of claim 1, wherein the light source slit of the slit cover of each of the first light source and the second light source extends in a direction that is perpendicular to the first direction.

3. The display apparatus of claim 1, wherein the light source slit of the slit cover of each of the first light source and the second light source extends in a direction that is perpendicular to a direction in which the first viewpoint and the second viewpoint are arranged.

4. The display apparatus of claim 1, wherein the at least one multi-view lens comprises a plurality of multi-view lenses, and
wherein the light source slit of the slit cover of each of the first light source and the second light source extends in a direction that is perpendicular to a direction in which the plurality of multi-view lenses are arranged.

5. The display apparatus of claim 1, wherein the light emitter of each of the first light source and the second light source comprises:
a first light emitter configured to emit light of first color;
a second light emitter configured to emit light of second color different from the first color; and
a third light emitter configured to emit light of third color different from the first color and the second color, and
wherein a direction in which the first light emitter, the second light emitter and the third light emitter are arranged is parallel with a direction in which the light source slit of the slit cover of each of the first light source and the second light source extends.

6. The display apparatus of claim 1, further comprising:
an entrance surface cover between the at least one multi-view lens and the first light source and the second light source, wherein the entrance surface cover comprises a lens slit having a second width,
wherein the lens slit is configured to allow light having passed through the light source slit of one of the first light source or the second light source to pass through the entrance surface cover and enter the at least one multi-view lens.

7. The display apparatus of claim 6, wherein the second width is equal to or smaller than the first width.

8. The display apparatus of claim 6, wherein the entrance surface cover is on an entrance surface of the at least one multi-view lens, and
wherein the entrance surface of the at least one multi-view lens is adjacent to the first light source and the second light source.

9. The display apparatus of claim 8, wherein the entrance surface cover comprises a light absorber coated on the entrance surface of the at least one multi-view lens.

10. The display apparatus of claim 6, wherein the lens slit comprises:
a first lens slit configured to allow at least a portion of light having passed through the light source slit of the first light source to pass through the entrance surface cover; and
a second lens slit arranged in parallel with the first lens slit and configured to allow at least a portion of light having passed through the light source slit of the second light source to pass through the entrance surface cover,
wherein a center of the light emitter of the first light source, a center of the light source slit of the first light source and a center of the first lens slit are arranged in a line, and
wherein a center of the light emitter of the second light source, a center of the light source slit of the second light source and a center of the second lens slit are arranged in a line.

11. The display apparatus of claim 1, wherein each of the first light source and the second light source further comprises a light source case accommodating the light emitter, and
wherein the slit cover of each of the first light source and the second light source is on a side of the light source case facing toward the at least one multi-view lens.

12. The display apparatus of claim 11, wherein each of the first light source and the second light source further comprises a transparent resin in the light source case enclosing the light emitter, and
wherein the slit cover of each of the first light source and the second light source covers a portion of the transparent resin on a side of the transparent resin facing toward the at least one multi-view lens.

13. The display apparatus of claim 1, wherein the slit cover of each of the first light source and the second light source comprises a light blocker around the light source slit and configured to block a portion of light emitted from the light emitter.

14. The display apparatus of claim 13, wherein the light blocker of each of the first light source and the second light source comprises a black coating layer configured to absorb a portion of light emitted from the light emitter.

15. The display apparatus of claim 13, wherein the light blocker of each of the first light source and the second light source comprises a reflective layer configured to reflect a portion of light emitted from the light emitter toward the light emitter.

16. A display apparatus comprising:
a first light source configured to emit light visible from a first viewpoint;
a second light source arranged in a row with the first light source in a first direction and configured to emit light visible from a second viewpoint different from the first viewpoint; and
a multi-view lens comprising an entrance surface on a side of the multi-view lens facing the first light source and the second light source, the entrance surface comprising a first lens slit corresponding to the first light source and a second lens slit corresponding to the second light source,
wherein the multi-view lens is configured to refract the light emitted from the first light source to proceed toward the first viewpoint and to refract the light emitted from the second light source to proceed toward the second viewpoint, and
wherein each of the first light source and the second light source comprises:
a light emitter; and
a light source case accommodating the light emitter, the light source case comprising:
a slit cover on a side of the light source case adjacent to the entrance surface of the multi-view lens, the slit cover covering a portion of the light emitter between the light emitter and the multi-view lens, the slit cover comprising a light source slit having a first width; and
a plurality of walls surrounding the light emitter, wherein an inner surface of at least one of the plurality of walls comprises a slanted surface and an interior width of the light source case increases in a direction moving away from the light emitter and toward the slit cover.

17. The display apparatus of claim 16, wherein the light source slit of the slit cover of each of the first light source and the second light source extends in a direction that is perpendicular to the first direction.

18. The display apparatus of claim 16, wherein the light source slit of the slit cover of each of the first light source and the second light source extends in a direction that is perpendicular to a direction in which the first viewpoint and the second viewpoint are arranged.

19. The display apparatus of claim 16, wherein the multi-view lens comprises a plurality of multi-view lenses, and
wherein the light source slit of the slit cover of each of the first light source and the second light source extends in a direction that is perpendicular to a direction in which the plurality of multi-view lenses are arranged.

20. The display apparatus of claim 16, wherein the first lens slit and the second lens slit have a second width, and
wherein the second width is equal to or smaller than the first width.
